(19) United States
(12) Patent Application Publication
(10) Pub. No.: US 2003/0175602 A1
(43) Pub. Date: Sep. 18, 2003

(54) Image forming method

(75) Inventor: Toshiyuki Kazama, Ebina-shi (JP)

Correspondence Address: Stephen P. Scuderi, Esq., McCormick, Paulding & Huber LLP, CityPlace II, 185 Asylum Street, Hartford, CT, 06103, US

(73) Assignee: FUJI XEROX CO., LTD., Tokyo (JP)

(21) Appl. No.: 10/375,856

(22) Filed: Feb. 26, 2003

(30) Foreign Application Priority Data
Mar. 15, 2002 (JP) 2002-071813

(51) Int. Cl. G03F 9/02; G03F 7/20; G03G 15/00; G03C 5/00; G03G 13/01; H04N 1/407; H04N 1/409; G06T 5/00; G06K 15/00

(52) U.S. Cl. 430/22; 430/30; 430/42; 399/1; 399/9; 358/3.26; 358/3.27

(57) ABSTRACT

High-precision registration of an image is enabled in a high speed and high quality color printer. A print control part carries out trial printing in double-sided printing. Images of both sides of the trial printing read by a scanner or the like are respectively compared with original images in an image analysis part, and deformations occurring in output images of both sides are analyzed. From this analysis result, a correction data generation part generates correction data, for both sides of a sheet, indicating a correction processing to be added to an input image to remove deformation occurring in an output image. An image correction part changes the correction data to be used according to which side of the sheet the input image is printed on, and corrects the input image. The print control part prints a corrected image.

### BACKGROUND OF THE INVENTION

1. Field of the Invention

The present invention relates to an image forming apparatus and an image forming method, in which image data is corrected so as to remove deformation occurring when an image is formed on a sheet and image formation is carried out.

2. Description of the Related Art

The improvement of output quality of a recent high speed and high quality color printer has been developed to such a level as to be comparable to printing with a plate.

Besides, with the digitization of information, a digital printer to realize on-demand printing has appeared, and the demand for color printers on the printing market has been increased.

In such a printer, high registration (register) performance is required.

However, according to a system of image formation, a printer having developed mainly in offices is weak in high-precision registration because of the change of an image magnification due to the deformation of a sheet, or the change of a registration amount.

In order to compensate such defects, as documents disclosing a method of carrying out registration by correcting magnifications of both sides, Japanese Patent Laid-Open No. 288560/1992 and No. 132673/1991 can be cited.

Besides, as documents disclosing a method of correcting the position of a sheet, Japanese Patent Laid-Open No. 249169/1992 and No. 46946/1991 can be cited.

### SUMMARY OF THE INVENTION

The present invention has been made in view of the above problems of the related art and provides an image forming apparatus and an image forming method, which enables high-precision registration (register) of an image in a high speed and high quality color printer.

An image forming method for forming an image from image data includes the steps of reading an image formed from the image data, detecting deformation of the formed image on the basis of the read image and an image indicated by the image data, and correcting the image data on the basis of a detection result of the deformation.

### BRIEF DESCRIPTION OF THE DRAWINGS

Preferred embodiments of the present invention will be described in detail based on the follow figures, wherein:

FIG. 1 is a view illustrating deformation of a sheet occurring when an image is fixed;

FIG. 2 is a view illustrating an out-of-skew and an out-of-registration occurring when a sheet is reversed;

FIG. 3 is a view illustrating rotation and slanting occurring in a case where printing is carried out using an intermediate transfer member;

FIG. 4 is a view illustrating deformation of an image when double-sided printing is carried out;

FIG. 5 is a view showing image formation by a general printer;

FIG. 6 is a view showing image formation to which a first image forming method of the invention is applied;

FIG. 7 is a first view showing image formation to which a second image forming method of the invention is applied;

FIG. 8 is a second view showing image formation to which the second image forming method of the invention is applied;

FIG. 9 is a view showing a method for correcting a part of image data;

FIG. 10 is a view illustrating a correction processing for registration adjustment in a fast-scanning direction and a slow-scanning direction;

FIG. 11 is a view illustrating a specific example of the correction shown in FIG. 10;

FIG. 12 is a view illustrating a correction processing for lead skew adjustment;

FIG. 13 is a view showing a specific example of the correction shown in FIG. 12;

FIG. 14 is a view illustrating a correction processing for side skew adjustment:

FIG. 15 is a view showing a specific example of the correction shown in FIG. 14;

FIG. 16 is a view illustrating a correction processing for magnification adjustment;

FIG. 17 is a view showing a specific example of the correction shown in FIG. 16;

FIG. 18 is a view illustrating a correction of a multicolor image;

FIG. 19 is a view illustrating a correction processing for bow shape adjustment;

FIG. 20 is a view showing a specific example of the correction shown in FIG. 19;

FIG. 21 is a view illustrating a correction processing for adjustment of part of an image;

FIG. 22 is a view showing a correction shown in FIG. 21;

FIG. 23 is a view showing a structure of a printer of the invention, laying stress on a control device;

FIG. 24 is a view showing a schematic structure of an apparatus main body shown in FIG. 23;

FIG. 25 is a view showing a structure of a print control program 4 for carrying out a shape data correction processing of an input image to remove deformation received by an output image;

FIG. 26 is a flowchart showing a first operation of a printer (FIG. 23, etc.); and

FIG. 27 is a flowchart showing a second operation of the printer (FIG. 23, etc.).

### DETAILED DESCRIPTION OF THE PREFERRED EMBODIMENTS

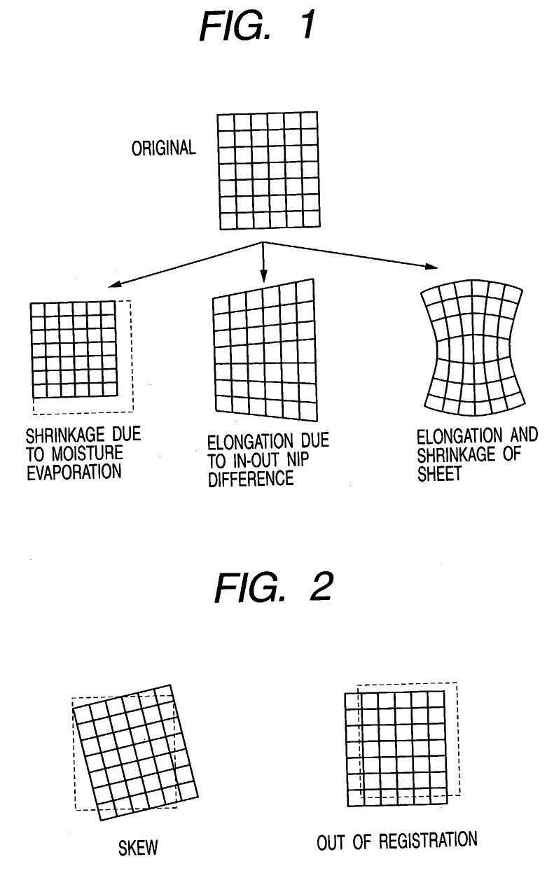

FIG. 1 is a view illustrating the deformation of a sheet occurring when an image is fixed.

As described before, a high speed and high quality color printer is required to have high-precision registration performance (register).

However, as shown in FIG. 1, in a printer/copying machine of a system in which toner is fixed to a sheet, moisture is evaporated by the influence of heat when an image is fixed on a sheet and the sheet is shrunk, or the sheet is stretched by the influence of pressure of the fixing processing.

When the shape of the sheet is changed as stated above, even in the case where printing is carried out on only one side of a sheet without carrying out double-sided printing, the shape of an image formed on the sheet is also changed.

FIG. 2 is a view illustrating an out-of-skew and an out-of-registration.

In the case where there is an out-of-skew or an out-of-registration as shown in FIG. 2, when double-sided printing is carried out using a reversing mechanism, the sheet is turned upside down, and the out-of-skew between both sides, and the out-of-registration with a cutting error of the sheet can noticeably appear.

In the case where double-sided printing is carried out, the shapes of images on both sides of the sheet can not be made coincident with each other by such a defect.

For example, even if an attempt is made to print lattice patterns (register marks) at the same positions of both sides of the sheet, there occurs a case where the positions of the lattice patterns on the front side and the back side are not coincident with each other.

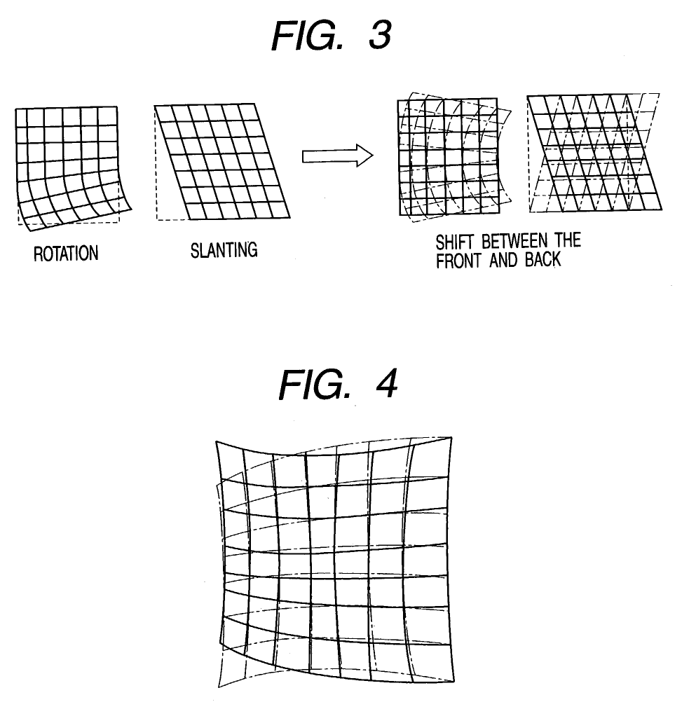

FIG. 3 is a view illustrating rotation and slanting occurring in the case where printing is carried out using an intermediate transfer member.

In the case where printing is carried out using the intermediate transfer member, as shown in FIG. 3, a difference in nip balance in an axial direction of a transfer part causes a difference between a direction in which an image is transferred and a traveling direction of a sheet, and the rotation or slanting can occur.

When such slanting/rotation occurs, there occurs such a defect that an image printed on the sheet becomes trapezoid or fan-shaped.

Until now, with respect to a shift in a fast-scanning direction, a video clock frequency is changed and a writing position is changed, and with respect to a shift in a slow-scanning direction, rotation speed of a polygon mirror, and a speed difference between image formation and a sheet are used, so that the enlargement and contraction of an image is carried out, and a contrivance to compensate a difference in image magnification between both sides of the sheet has been made.

However, in the case where the magnifications in the fast and slow scanning directions are changed at the same time, although the enlargement and contraction in the fast-scanning direction can be instantaneously realized by changing the clock frequency or the like, it is difficult to instantaneously realize the enlargement and contraction in the slow-scanning direction since the change of rotation speed of a motor is accompanied with a delay.

On the other hand, in order to correct the out-of-registration, there is adopted a method in which timing when an image is printed on a sheet, or timing of delivery of a sheet is adjusted.

However, even if such adjustment is carried out, it is impossible to correct deformations such as skew, rotation, trapezoid and fan shape.

Accordingly, as shown in FIG. 4, in the case where images are deformed in a state where these deformations are compositely combined on the front and back in double-sided printing, still another mechanism is needed in order to correct such deformation as skew or trapezoid. However, even if such a mechanism is provided, it is difficult to completely correct the composite deformation.

Besides, the addition of such a mechanism increases the scale of the apparatus and its cost.

Further, when an attempt to cope with the foregoing defects by mechanical unit is made, an adjustment for adapting the apparatus to a change is needed each time the size and kind of a sheet or the environment is changed.

Besides, for example, in the case where defects of different tendencies occur according to a printing surface, in order to carry out double-sided printing by alternately changing the printing surface between the front and back, each time the print surface is changed, the mechanism for correcting the defect must be also exchanged.

As stated above, in the case where both sides of a sheet are alternately printed, it is difficult to adopt a method for correcting the defect by mechanical unit.

The present invention has been made in view of such facts, and deformation occurring on an image is corrected without relying on mechanical unit, and further, a contrivance is made such that in the case where double-sided printing is carried out, images on both sides of a sheet are made coincident with each other.

[Deformation and its correction]

As the outline of the present invention, first, deformation received by an image and its correction will be described.

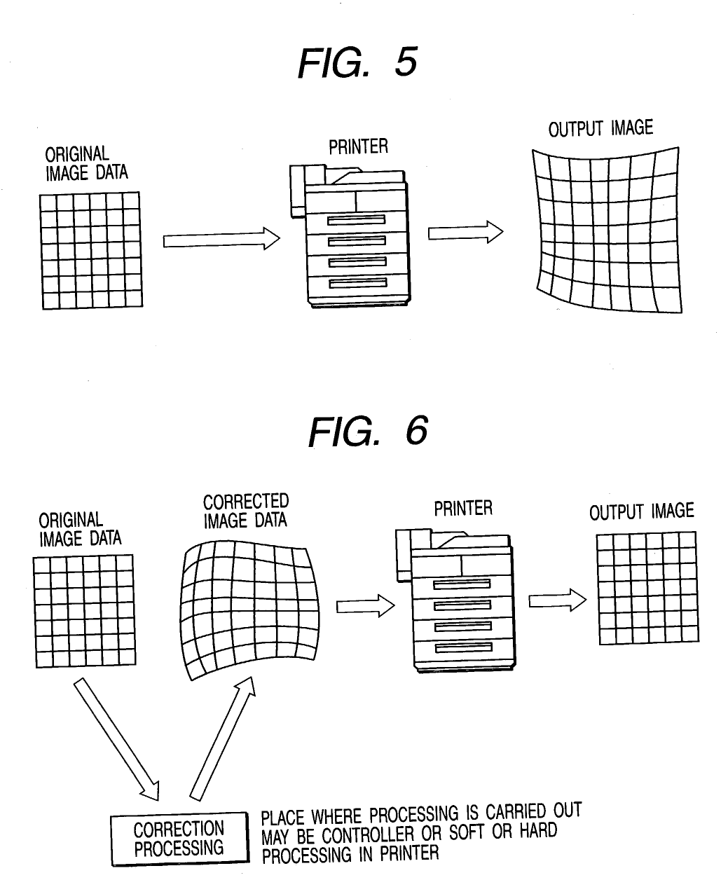

FIG. 5 is a view showing image formation by a general printer.

FIG. 6 is a view showing image formation to which a first image forming method of the invention is applied.

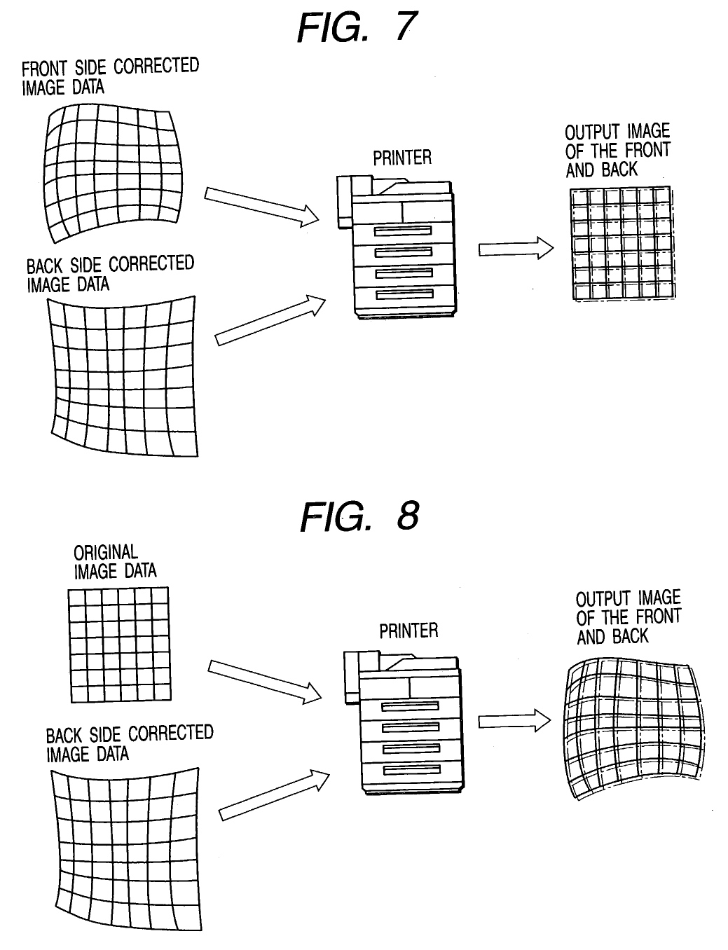

FIG. 7 is a first view showing image formation to which a second image forming method of the invention is applied.

When an image is printed (formed) on a sheet without taking countermeasures against the deformation, an output image obtained as the result can be deformed as described with reference to FIGS. 1 to 4.

In the case where double-sided printing is carried out, the shapes of images on both sides of a sheet can not be coincident with each other by the deformation occurring at the time of printing.

On the other hand, as shown in FIG. 6, deformation received by an image at the time of printing is measured in advance, and a shape data correction processing of an original image data to eliminate (remove) the deformation received at the time of printing is carried out to form corrected image data, and when this corrected image data is printed, a correct output image can be obtained.

Besides, in the case where double-sided printing is carried out, deformation occurring on an image when printing is carried out on one side (front side) of a sheet can be different from deformation occurring on an image when printing is carried out on the other side (back side) of the sheet.

In such a case, deformations different between both sides of a sheet are separately measured in advance, and with respect to the image to be printed on the front side, correction for removing the deformation occurring when the front side is printed is carried out to obtain front side corrected image data, and with respect to the image to be printed on the back side, correction for removing the deformation occurring when printing is carried out on the back side is carried out to form back side corrected image data, and when printing is carried out, the shapes of images on both sides of the sheet can be made coincident with each other.

Incidentally, unless the correction to make one of images of both sides coincident with the other, or the correction to cancel the deformations of images of both sides is carried out, for example, even when an average value of deformations received by images of both sides is obtained, and a correction to cancel the average value of the deformations is carried out for the image data to be printed on both surfaces, the shapes of output images on both sides of the sheet can be made coincident with each other (see FIG. 7).

FIG. 8 is a second view showing image formation to which the second image forming method of the invention is applied.

In the method shown in FIG. 8, in order to cause shapes of images on both sides of a sheet to be coincident with each other, original image data to which a correction is not added is printed on the front side and deformation is allowed to occur in the output image.

On the other hand, data to be printed on the back side is corrected to generate back side corrected data so that the same deformation as the image data printed on the front side is received after printing, and a contrivance is made such that when this back side corrected data is printed, the same deformation as the front side is received.

As shown in FIG. 8, by correcting image data of one of both sides as well, the shapes of the images of both sides can be made coincident with each other when double-sided printing is carried out.

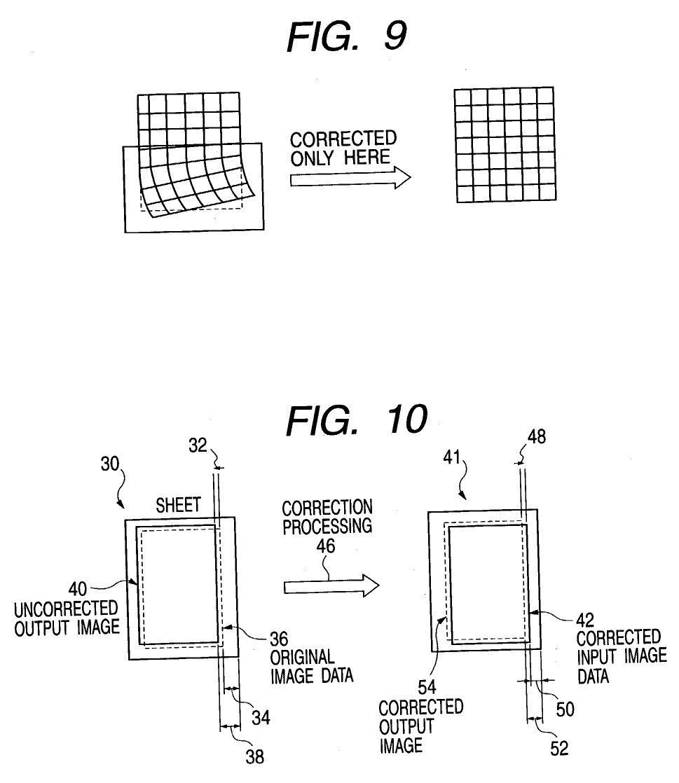

FIG. 9 is a view showing a method of correcting a part of image data.

As shown in FIG. 9, deformation can occur in a part at the time of printing.

In such a case, when a correction is applied to only the part of the image data where the deformation has occurred and printing is carried out, deformation of an output image can be removed.

[Correcting method]

Next, a correcting method will be specifically described.

Incidentally, in the following description of the correcting method, 2400×2400 DPI (dot interval 0.0106 mm) is made a specific example.

[Registration correction]

FIG. 10 is a view for illustrating a correction processing for registration adjustment in the fast-scanning direction and slow-scanning direction.

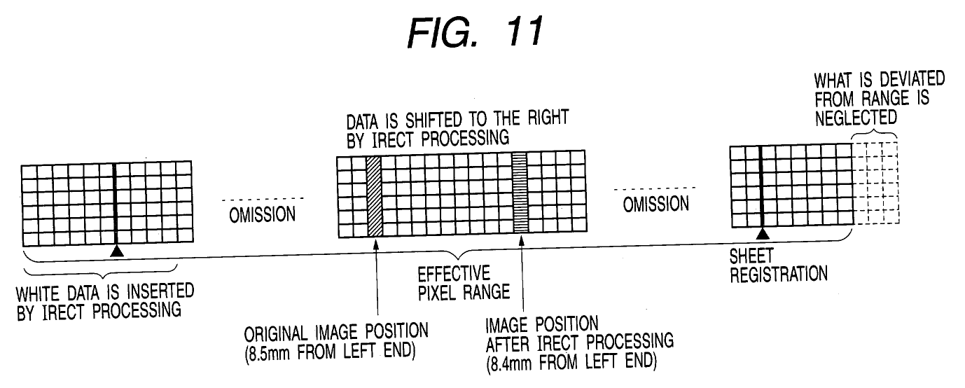

FIG. 11 is a view showing a specific example of the correction shown in FIG. 10.

As shown on the left side 30 of FIG. 10, consideration will be given to a case where for example, printing is carried out to be shifted to the left by 0.1 mm (as indicated by arrow 32) so that side registration (side register) of 8.5 mm 34 of the right side of original image data 36 becomes 8.6 mm 38 in an actual output image 40.

In such a case, as shown on the right side 41 of FIG. 10, printing has only to be carried out after input image data 42 is corrected by a shape data correction processing 46 so that it is moved to the right by 0.1 mm 48 in advance.

That is, when printing is carried out after the side registration of the right side of the input image data 42 is made 8.4 mm 50, the input data is shifted to the left by 0.1 mm by printing so that the side registration becomes 8.5 mm 52, and the output image 54 having the same side registration 34 as the original image data 36 can be obtained.

As stated above, in order to cancel the shift of the register in the fast-scanning direction and slow-scanning direction in the output image, correction for moving the input image in the reverse direction to the shift occurring in the output image and by the same length has only to be carried out in advance.

Further, correction of the side registration will be described in detail.

A correction for moving an input image to the right by 0.1 mm is carried out as described below.

As shown on the left side of FIG. 11, white pixels are inserted into a region within 0.1 mm from the left end of the input image.

Besides, as shown on the left side, center, and right side of FIG. 11, pixels of the other region are respectively moved to the right by 0.1 mm.

Besides, as shown on the right side of FIG. 11, pixels of a region within 0.1 mm from the right end of the input image, that is, pixels in a region which are protruded from a drawing region when they are moved to the right by 0.1 mm, are thinned out (neglected).

[Lead skew correction]

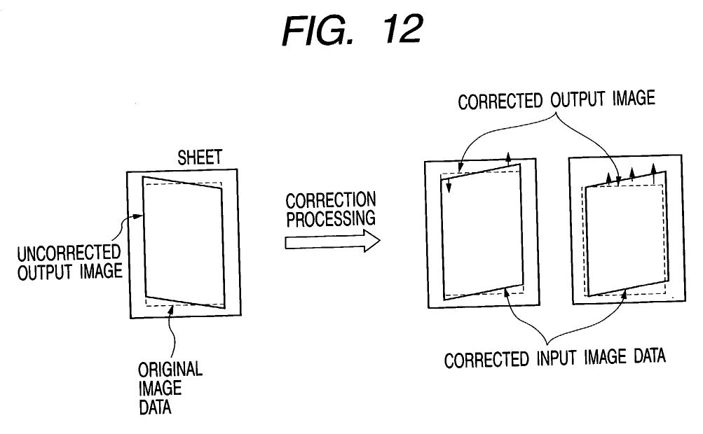

FIG. 12 is a drawing illustrating a correction processing for lead skew adjustment.

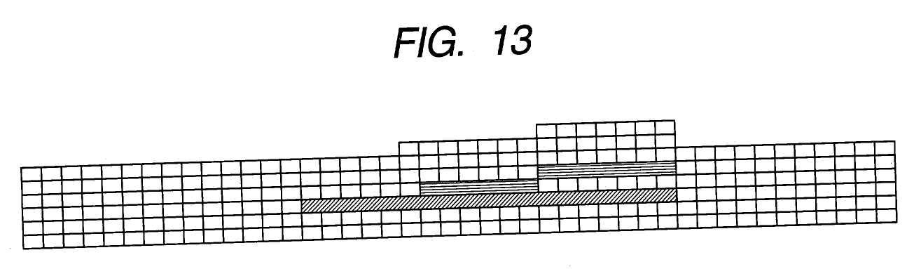

FIG. 13 is a view showing a specific example of the correction shown in FIG. 12.

As shown on the left side of FIG. 12, in the case where the lead skew occurs in an output image, as shown on the right side of FIG. 12, a correction has only to be carried out such that the same amount of lead skew is given to an input image in the reverse direction to the lead skew in the output image.

Incidentally, although two examples of modes of the correction processing are shown on the left side of FIG. 12, the left side of these examples indicates, as shown by arrows, a correction carried out in the case where the left side of the output image is shifted upward and the right side is shifted downward.

Besides, the right side of these examples indicates, as shown by arrows, a correction carried out in the case where the left end of the output image is not shifted, and the output image is more shifted downward as it goes right.

As shown in FIG. 13, the correction of the lead skew is also carried out by the movement, insertion and thinning of pixels, similarly to the case of the registration adjustment shown in FIG. 11.

[Side skew correction]

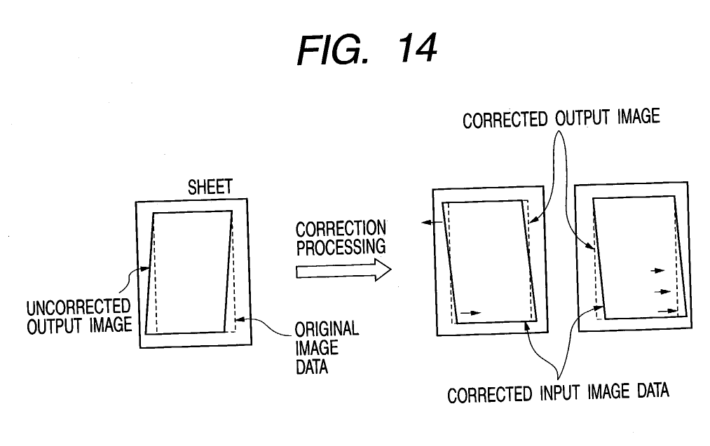

FIG. 14 is a view illustrating a correction processing for side skew adjustment.

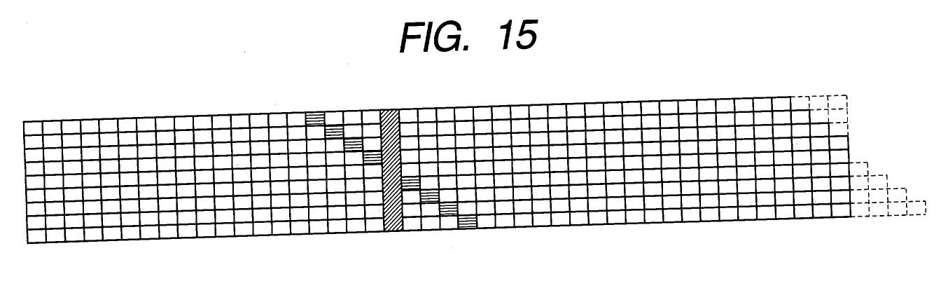

FIG. 15 is a view showing a specific example of the correction shown in FIG. 14.

As shown on the left side of FIG. 14, in the case where the side skew occurs in an output image, as shown on the right side of FIG. 14, similarly to the case of the foregoing lead skew adjustment, a correction has only to be carried out such that the same amount of side skew is given to an input image in the reverse direction to the side skew in the output image.

Incidentally, similarly to the lead skew adjustment shown in FIG. 12, two examples of modes of the correction processing are shown on the left side of FIG. 14, and the left side of these examples shows, as indicated by arrows, a correction carried out in the case where the upper side of an output image is shifted to the right direction, and the lower side thereof is shifted to the left direction.

Besides, the right side of these examples shows, as indicated by arrows, a correction carried out in the case where the upper end of the output image is not shifted, but the output image is more shifted toward the left direction as it goes downward.

As shown in FIG. 15, similarly to the case of the registration adjustment and the lead skew adjustment shown in FIGS. 11 and 13, the correction of the side skew is also carried out by the movement, insertion and thinning of pixels.

[Magnification correction]

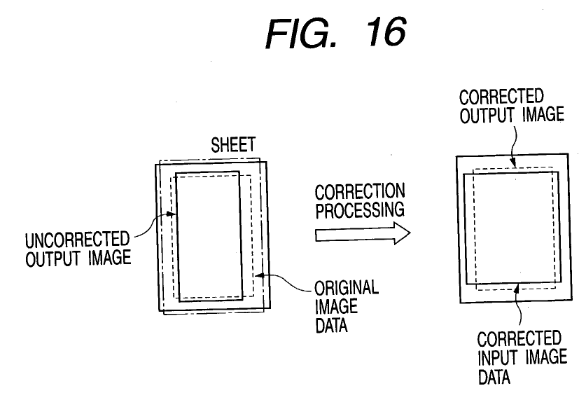

FIG. 16 is a view illustrating a correction processing for magnification adjustment.

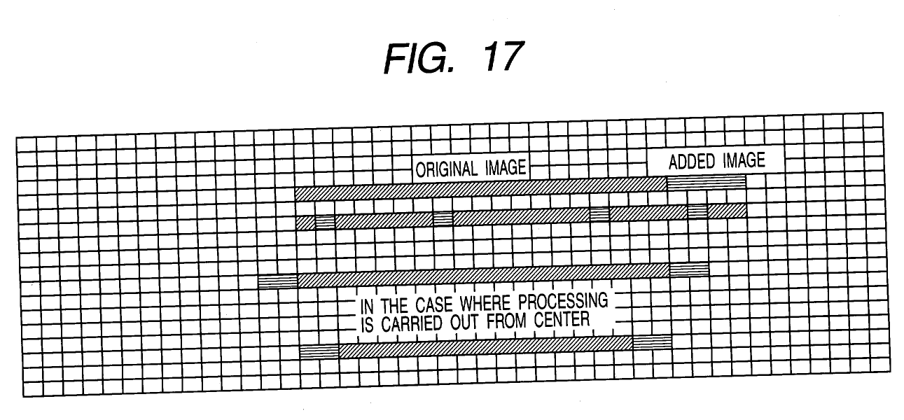

FIG. 17 is a view showing a specific example of the correction shown in FIG. 16.

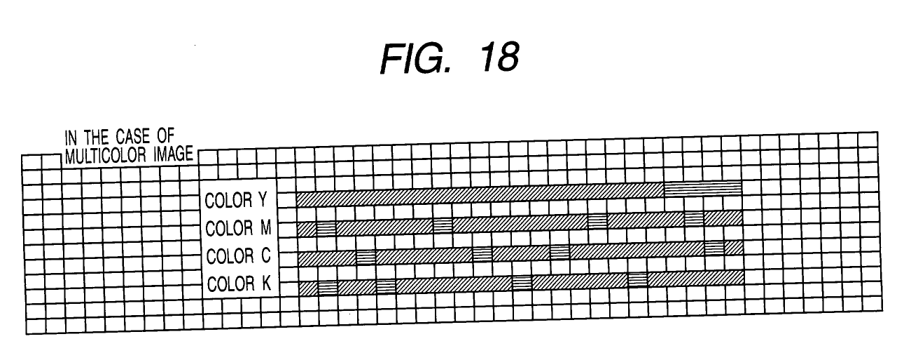

FIG. 18 is a view illustrating correction of a multicolor image.

As shown on the left side of FIG. 16, a print sheet is deformed in the horizontal direction by heat or the like so that it becomes long in the vertical direction, an output image receives similar deformation, and its magnification can be changed.

In such a case, as shown on the right side of FIG. 16, a correction of an input image has only to be carried out such that the change occurring in an output image is cancelled, that is, magnification is adjusted to shorten the image in the vertical direction and to lengthen it in the horizontal direction.

The correction of the magnification is carried out such that as shown in the uppermost part of FIG. 17, pixels are added to one end of an input image, or as shown in the second part from above in FIG. 17, pixels are inserted into an input image at suitable intervals.

Further, as shown in the third and fourth parts from above in FIG. 17, this correction can also be carried out by adding pixels to both ends of an image.

Further, in the case where an image is multicolored, when pixels are inserted to the respective colors in the same modes, a disturbance of an image due to the insertion of pixels occurs, and its appearance becomes worse.

Accordingly, in such a case, as shown in FIG. 18, it is appropriate that pixels are inserted to the input image by a different mode for each color.

[Bow shape correction]

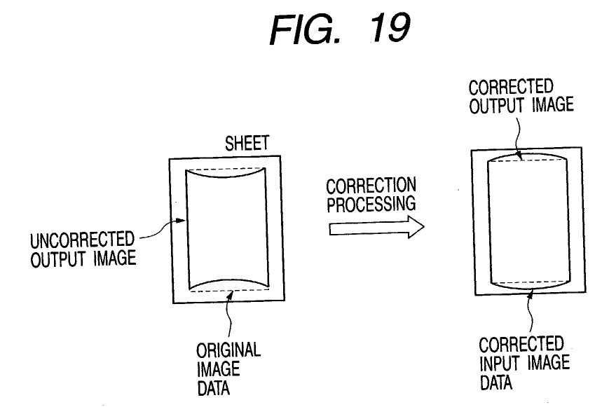

FIG. 19 is a view illustrating a correction processing for bow shape adjustment.

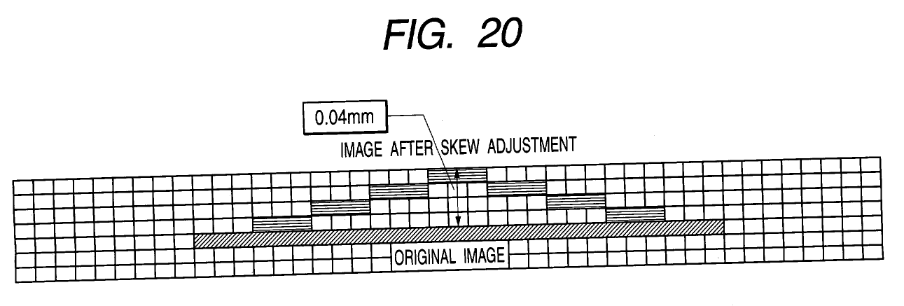

FIG. 20 is a view showing a specific example of the correction shown in FIG. 19.

As shown on the left side of FIG. 19, a printing sheet is deformed by heat or the like, and in accordance with this, an output image can receive a bow shape distortion in which the center portion is shrunk in the vertical direction.

In such a case, as shown on the right side of FIG. 20, a correction to an input image has only to be carried out such that the change occurring in the output image is cancelled, that is, the center portion becomes convex.

This correction is carried out by, as shown in FIG. 20, the movement, insertion and thinning of pixels.

[Correction of part of an image]

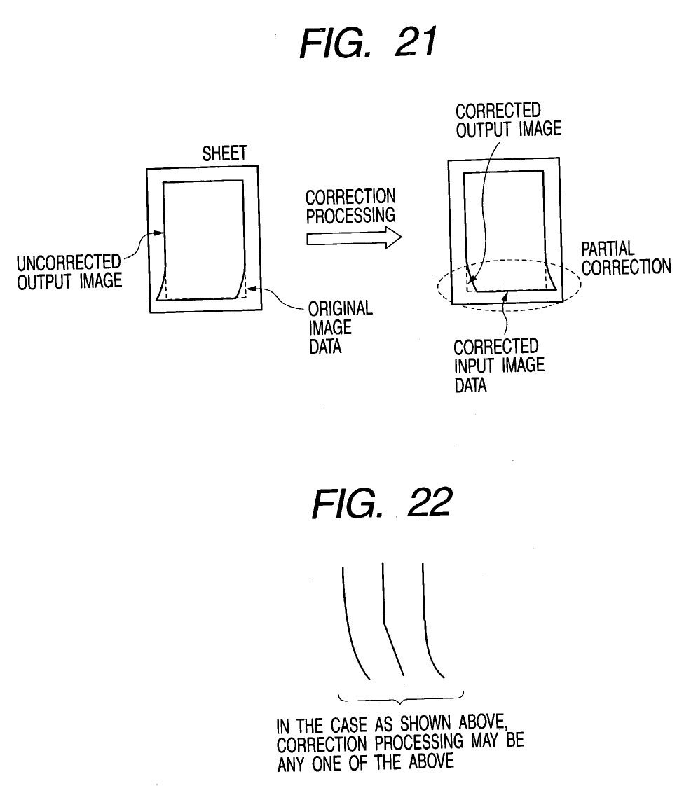

FIG. 21 is a view illustrating a correction processing for adjustment of a part of an image.

FIG. 22 is a view showing the correction shown in FIG. 21.

As shown on the left side of FIG. 21, only a part of an output image receives deformation by a defect of sheet feeding or the like.

In such a case, as shown on the right side of FIG. 21, a correction has only to be carried out such that deformation to cancel the change occurring in the o output image is given to an input image.

As shown in FIG. 22, in this correction, with respect to a portion of an input screen where correction is carried out, such a correction that a movement amount of each pixel is smoothly changed may be given, such a correction that a movement amount of a pixel is approximated by polygons may be given, or a correction of combination of these may be given.

[Printer]

Hereinafter, as an embodiment of the present invention, a description will be given of a printer 1 for carrying out printing after the above explained shape data correction processing of an input image is carried out.

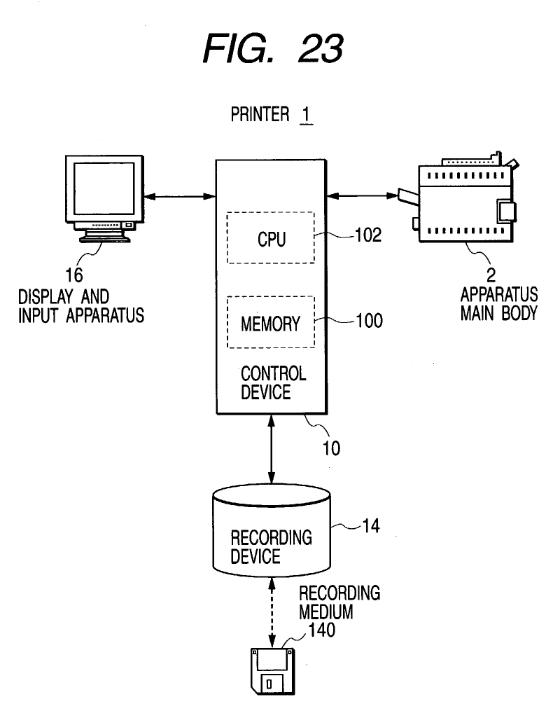

FIG. 23 is a view showing a structure of the printer 1 of the invention laying stress on a control device 10.

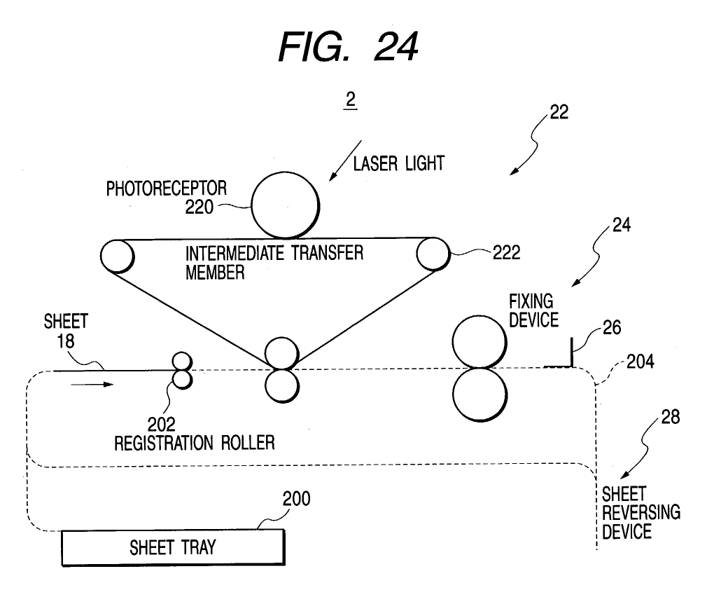

FIG. 24 is a view showing a schematic structure of an apparatus main body 2 shown in FIG. 23.

As shown in FIG. 23, the printer 1 is constituted by the copying apparatus main body 2, the control device 10 constituted by a memory 100, a CPU 102 and the like, a recording device 14 such as a CD-ROM or an HDD, and a display and input device 16 including a display device, a keyboard and the like.

The control device 10 and the recording device 14 are actually housed in the copying apparatus main body 2.

As shown in FIG. 24, the copying apparatus main body 2 (FIG. 23) is constituted by a sheet tray 200, a registration roller 202, a sheet transporting passage 204, an image transfer part 22 including a photoreceptor 220, an intermediate transfer member 222 and the like, a fixing device 24, a scanner 26, and a sheet reversing device 28.

That is, the printer 1 includes a structural portion as a general printer for carrying out an image formation (printing) in which an image of image data supplied from, for example, a network (not shown) is transferred with toner in the image transfer part 22 onto a sheet 18 fed from the sheet tray 200, and is fixed by the fixing device 24, and the scanner 26 for reading an output image.

Incidentally, the respective structural parts of the copying apparatus main body 2 operate in accordance with the control of the control device 10 (FIG. 23).

Besides, the copying apparatus main body 2 may be of such a type that printing is carried out directly from the photoreceptor 220 to the sheet 18 without the intermediate transfer member 222, and may be of another type in which plural image transfer parts 22 are included.

[Print control program 4]

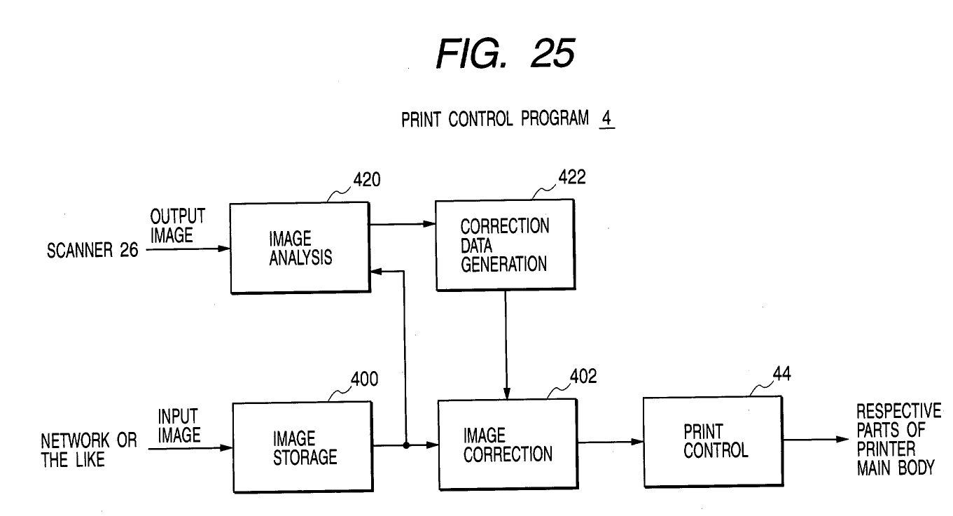

FIG. 25 is a view showing a structure of a print control program 4 for carrying out a shape data correction processing of an input image so as to cancel deformation received by an output image.

As shown in FIG. 25, the print control program 4 is constituted by an image storage part 400, an image correction part 402, an image analysis part 420, a correction data generation part 422, and a print control part 44.

The print control program 4 is supplied to the recording device 14 by, for example, a recording medium 140 (FIG. 23), and is loaded into the memory 100 and is executed.

By these structural parts, the print control program 4 analyzes a change occurring in an output image in the copying apparatus main body 2 (FIG. 23, FIG. 24), carries out a correction of the input image to cancel the change, and effects printing.

Incidentally, the respective structural parts of the print control program 4 are constructed as program modules, and can be suitably added and deleted.

Besides, the respective structural parts of the print control program 4 are started and executed at arbitrary timing by an OS or the like, or can be interrupted as the need arises.

[Image storage part 400]

The image storage part 400 stores the data of an input image which is inputted from the network (not shown) or the like and becomes an object of a shape data correction processing by the print control program 4 and print processing, and outputs it to the image correction part 402 and the image analysis part 420.

[Image analysis part 420]

The image analysis part 420 uses the scanner 26 of the copying apparatus main body 2 (FIG. 23, FIG. 24), and reads an output image of a test pattern (for example, a lattice pattern (register mark) shown in FIG. 1) printed on the sheet 18 by the image transfer part 22.

Besides, the image analysis part 420 compares the read output image with the input image of the test pattern inputted from the image storage part 400, analyzes which deformation shown in FIGS. 10 to 22 has been added to the output image, or deformation of which combination of these has been added, and outputs an analysis result to the correction data generation part 422.

Incidentally, in the case where the printer 1 carries out double-sided printing, the image analysis part 420 generates separate analysis results concerning the front side and the back side.

Alternately, the image analysis part 420 makes the kind and shape of the sheet 18 (FIG. 24) correspond to the analysis result of deformation occurring in the output image, and stores them, and in accordance with the kind and shape of the sheet 18 specified through the display and input device 16 or the like, the image analysis part outputs the analysis result of the deformation occurring in the output image to the correction data generation part 422.

Incidentally, in the case where the image analysis part 420 carries out only the operation as stated above, the scanner 26 (FIG. 24) is not necessarily required.

[Correction data generation part 422]

The correction data generation part 422 generates, on the basis of the analysis result inputted from the image analysis part 420, correction data indicating what correction should be made to the input image to cancel the deformation occurring in the output image, and outputs it to the image correction part 402.

That is, the correction data generated by the correction data generation part 422 indicates the shape data correction processing shown in FIG. 11, 13, 15, 17, 18, 20 or 22, or a combination of these correction processings to cancel the deformation occurring in the output result, shown in FIG. 10, 12, 16, 19 or 21, or a combination of these deformations.

Incidentally, in the case where the printer 1 carries out double-sided printing, the correction data generation part 422 generates separate correction data concerning the front side and the back side.

[Image correction part 402]

The image correction part 402 carries out the shape data correction processing of the data of the input image in accordance with the correction data inputted from the correction data generation part 422, and outputs it as corrected image data to the print control part 44.

Incidentally, in the case where the printer 1 carries out double-sided printing, the image correction part 402 corrects the input image to be printed on the front side by using the correction data generated for the front side, and corrects the input image to be printed on the back side by using the correction data generated for the back side.

[Print control part 44]

The print control part 44 controls the respective structural parts (FIG. 24) of the copying apparatus main body 2, and causes the corrected image data inputted from the image correction part 402 to be printed.

[Operation (1) of the printer 1]

Hereinafter, a first operation of the printer 1 in which the image analysis part 420 receives the specification of the kind and shape of the sheet 18 and outputs the analysis result, will be described.

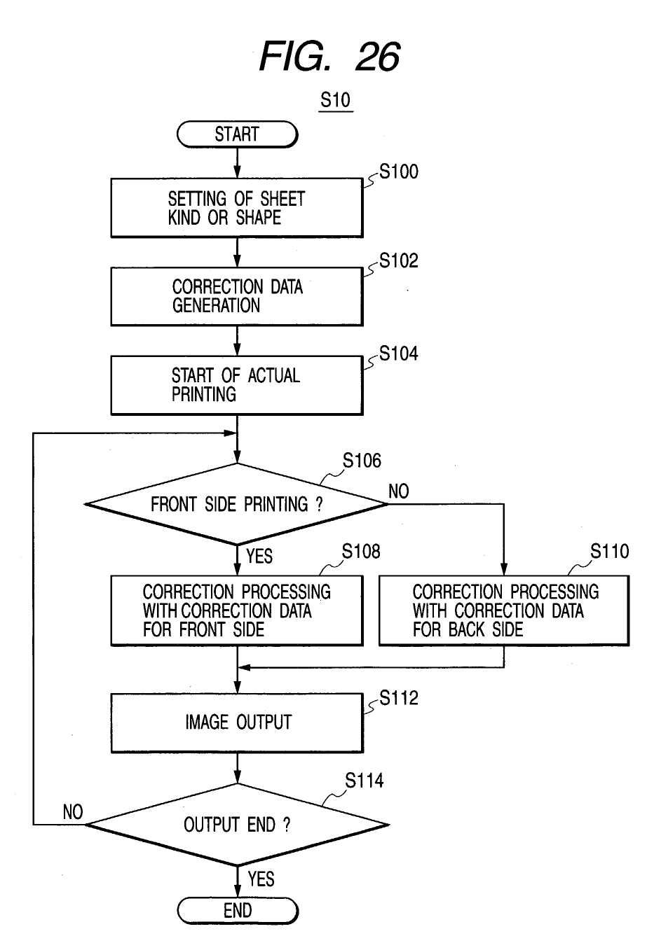

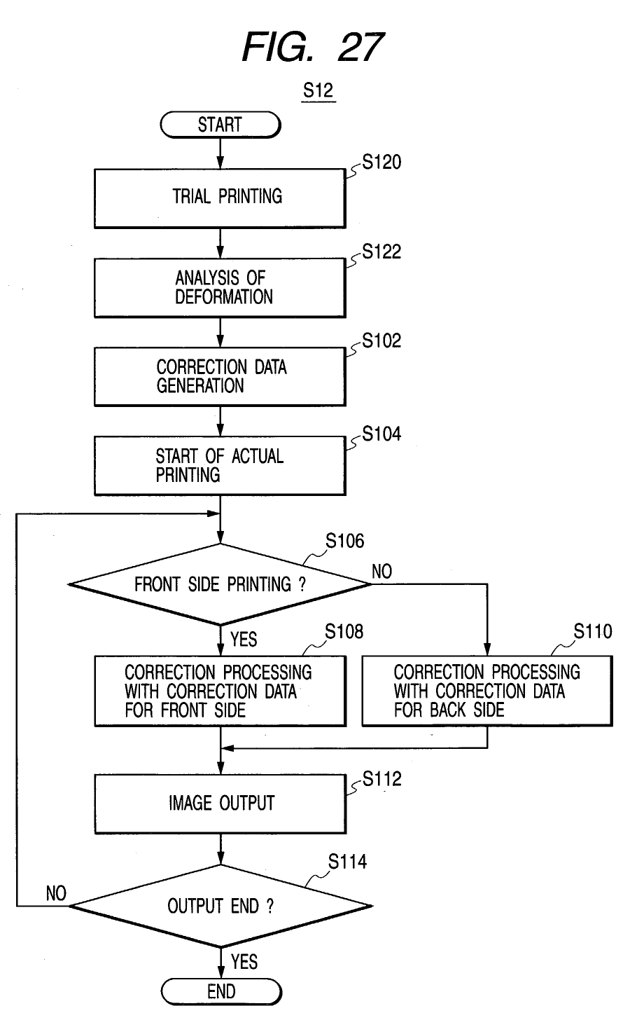

FIG. 26 is a flowchart showing the first operation of the printer 1 (FIG. 23, etc.).

As shown in FIG. 26, at step 100 (S100), the image analysis part 420 (FIG. 25) receives the specification of the kind and shape of the sheet 18 (FIG. 24) through the display and input device 16.

At step 102 (S102), the image analysis part 420 outputs the analysis result of a change amount corresponding to the specified kind and shape of the sheet 18 to the correction data generation part 422.

The correction data generation part 422 generates the correction data on the basis of the analysis result inputted from the image analysis part 420 and outputs it to the image correction part 402.

At step 104 (S104), the print control program 4 starts actual printing (press run) to the sheet 18.

At step 106 (S106), the image correction part 402 judges whether or not the input image is to be printed on the front side, and in the case where the input image is to be printed on the front side, the procedure proceeds to processing of S108, and in the case other than this, it proceeds to processing of S110.

At step 108 (S108), the image correction part 402 corrects the input image data using the correction data for the front side, and outputs it as the corrected image data to the print control part 44.

Incidentally, in the case where the printer 1 carries out one side printing on the plural sheets 18, only the processing of S108 is executed.

At step 110 (S110), the image correction part 402 corrects the input image data using the correction data for the back side to form corrected image data, and outputs it to the print control part 44.

At step 112 (S112), the print control part 44 controls the respective structural parts of the copying apparatus main body 2, and prints the corrected image data inputted from the image correction part 402 on the sheet 18.

At step 114 (S114), the print control program 4 judges whether or not the output (printing) of the image is ended, and terminates the processing in the case where it is ended, and in the case other than this, it returns to the processing of S106.

[Operation (2) of the printer 1]

Hereinafter, a second operation of the printer 1 in which the image analysis part 420 uses an output image read by the scanner 26 to analyze deformation of the output image, will be described.

FIG. 27 is a flowchart showing the second operation of the printer 1 (FIG. 23, etc.).

Incidentally, in FIG. 27, the same processing as the first operation (FIG. 26) is designated by the same symbol.

At step 120 (S120), the print control part 44 carries out double-sided printing, and prints (trial printing) a test pattern on both sides of the sheet 18.

At step 122 (S122), the scanner 26 (FIG. 24) reads images printed on both the sides of the sheet 18, and outputs them to the image analysis part 420 (FIG. 25).

The image analysis part 420 compares the output images of both the sides of the sheet 18 inputted from the scanner 26 with the input images of the test pattern inputted from the image storage part 400, analyzes the deformations occurring in the output images of both the sides of the sheet 18, and outputs the analysis results to the image correction part 402.

At S102 to S114, the print control program 4 carries out the processings shown in FIG. 27 and given the same symbols, and effects printing on the sheet 18.

Incidentally, although the description has been given of the copying machine having the built-in scanner, it is needless to say that the invention can be applied to the system in which an image read by an independent scanner is read into a printer offline and is printed.

As described above, according to the image forming apparatus and the image forming method of the invention, in a high speed and high quality color printer or the like, high-precision registration (register) of images can be carried out.

The entire disclosure of Japanese Patent Application No. 2002-071813 filed on Mar. 15, 2002 including specification, claims, drawings and abstract is incorporated herein by reference in its entirety.

What is claimed is:

1. An image forming method for forming an image from image data, comprising the steps of:
reading an image formed from image data;
detecting deformation of the formed image on the basis of the read image and an image indicated by the image data; and
correcting the image data on the basis of a detection result on the deformation.

2. The image forming method according to claim 1, wherein:
the deformation of the formed image includes at least one of a skew, a bow shape, a magnification change and a registration deformation.

3. The image forming method according to claim 1, further comprising:
forming and fixing an image on a sheet from image data; and
reading the image formed and fixed on the sheet.

4. An image forming method for forming images on respective plural surfaces from image data, comprising the steps of:
reading images formed on the respective plural surfaces, to obtain image data; and
correcting the image data to make the read images coincident with each other.

5. The image forming method according to claim 4, wherein:
images are formed on both sides of a sheet from the image data;
the images formed on both the sides of the sheet are read; and
the image data is corrected to remove a difference between the images read from both the sides of the sheet.

6. A storage medium readable by a computer, the storage medium storing a program of instructions executable by the computer to perform a function for forming an image from image data, the function comprising the steps of:
reading an image formed from image data;
detecting deformation of the formed image on the basis of the read image and an image indicated by the image data; and
correcting the image data on the basis of a detection result on the deformation.

7. A method of correction processing image data comprising:
inputting original image data into a printing process to print an uncorrected output image;
reading the uncorrected output image to obtain uncorrected output image data;
comparing the uncorrected output image data to the original image data to determine deformations due to the printing process;
generating correction data required to substantially reduce the deformations;
modifying input image data in accordance with the correction data to provide corrected image data; and
inputting the corrected image data into the printing process to print an output image having substantially reduced deformations due to the printing process.

8. The method of claim 7 wherein modifying the input image data comprises any one of:
moving of pixels;
inserting of pixels; and
thinning of pixels.

9. The method of claim 7 wherein the original image data comprises front and back side original image data.

10. The method of claim 9 comprising:
generating front and back side correction data;
modifying front and back side input image data in accordance with the front and back side correction data to provide front and back side corrected image data respectively; and
inputting the front and back side corrected image data into the printing process to print front and back side images onto a print medium.

11. The method of claim 10 comprising:
averaging the front and back side correction data to provide averaged correction data; and
modifying the front and back side input image date in accordance with the averaged correction data.

12. The method of claim 7 wherein:
the deformations due to the printing process include at least one of a skew, a bow shape, a magnification change and a registration deformation.

13. A printing system for correction processing image data comprising:
a printing device for providing a printing process; and
a control device for controlling the printing device, the control device including a memory having an executable program for:
inputting original image data into the printing process to print an uncorrected output image;
reading the uncorrected output image to obtain uncorrected output image data;
comparing the uncorrected output image data to the original image data to determine deformations due to the printing process;
generating correction data required to substantially reduce the deformations;
modifying input image data in accordance with the correction data to provide corrected image data; and
inputting the corrected image data into the printing process to print an output image having substantially reduced deformations due to the printing process.

14. The printing system of claim 13 wherein the program comprises:
modifying the input image data by any one of:
moving of pixels;
inserting of pixels; and
thinning of pixels.

15. The printing system of claim 13 wherein the original image data comprises front and back side original image data.

16. The printing system of claim 15 wherein the program comprises:
generating front and back side correction data;
modifying front and back side input image data in accordance with the front and back side correction data to provide front and back side corrected image data respectively; and
inputting the front and back side corrected image data into the printing process to print front and back side images onto a print medium.

17. The printing system of claim 16 wherein the program comprises:
averaging the front and back side correction data to provide averaged correction data; and
modifying the front and back side input image date in accordance with the averaged correction data.

18. The printing system of claim 13 wherein:
the deformations due to the printing process include at least one of a skew, a bow shape, a magnification change and a registration deformation.
